(19) United States
(12) Patent Application Publication
(10) Pub. No.: US 2025/0227990 A1
(43) Pub. Date: Jul. 10, 2025

(54) COMPLEMENTARY FIELD-EFFECT TRANSISTORS

(71) Applicant: Applied Materials, Inc., Santa Clara, CA (US)

(72) Inventors: San-Kuei Lin, Los Gatos, CA (US); Pradeep K. Subrahmanyan, Los Gatos, CA (US)

(73) Assignee: Applied Materials, Inc., Santa Clara, CA (US)

(21) Appl. No.: 19/007,852

(22) Filed: Jan. 2, 2025

Related U.S. Application Data
(60) Provisional application No. 63/618,676, filed on Jan. 8, 2024.

(51) Int. Cl. H10D 84/85; H10D 30/00; H10D 30/01; H10D 30/40; H10D 62/10; H10D 84/01

(52) U.S. Cl. CPC H10D 84/851; H10D 30/014; H10D 30/019; H10D 30/40; H10D 30/501; H10D 62/121; H10D 84/0167

(57) ABSTRACT

Methods of manufacturing electronic devices are described. Embodiments of the present disclosure advantageously provide methods of manufacturing electronic devices, e.g., complementary field-effect transistors (CFETs) that have improved negative bias temperature (NBTI) and boosted performance of the PMOS transistor due to the presence of a silicon germanium (SiGe) channel in the PMOS transistor. Specifically, a plurality of nanosheet release layers is removed from the N-channel metal-oxide-semiconductor (NMOS) transistor to form a plurality of openings adjacent the corresponding plurality of nanosheet channel layers, and a plurality of oxide layers are deposited in each of the plurality of openings.

### CROSS REFERENCE TO RELATED APPLICATIONS

This application claims priority to U.S. Provisional Application No. 63/618,676, filed Jan. 8, 2024, the entire disclosure of which is hereby incorporated by reference herein.

### TECHNICAL FIELD

Embodiments of the present disclosure pertain to the field of electronic device manufacturing, and in particular, to transistors. More particularly, embodiments of the disclosure are directed to complementary field-effect transistors (CFETs) and methods of manufacturing CFETs.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate planar field-effect transistors (FETs) in which current flows through a semiconducting channel between a source and a drain, in response to a voltage applied to a control gate.

One example of GAA technology is complementary field-effect transistor (CFET), where “N-channel metal-oxide-semiconductor (NMOS) FETs” and “P-channel metal-oxide-semiconductor (PMOS) FETs” are vertically stacked on top of each other. CFETs have increased on-chip device density and reduced area consumption compared to GAA transistors. When stacking NMOS FETs and PMOS FETs in a monolithic manner, the n and p superlattice (e.g., the NMOS FET or PMOS FET, respectively) are deposited sequentially with a middle sacrificial layer that is selectively removed and replaced with a middle dielectric isolation (MDI) layer during processing. The MDI layer serves to electrically isolate the lower-level GAA from the upper-level GAA.

One of the challenges in integrating CFET technology is the negative bias temperature instability (NBTI) issue that affects the NMOS device due to the diffusion of germanium (Ge) into the silicon (Si) channel during high thermal budget processes, such as the epitaxial (epi) process. Additionally, the PMOS device lacks a mobility booster, resulting in a performance gap when compared to the NMOS device, mainly due to the silicon (Si) orientation setup at <100>.

Accordingly, there is a need for improved CFET devices and methods of manufacturing CFETs.

### SUMMARY

One or more embodiments of the disclosure are directed to a method of forming a complementary field-effect transistor (CFET). The method comprises: removing a plurality of nanosheet release layers from a N-channel metal-oxide-semiconductor (NMOS) transistor to form a plurality of openings adjacent a corresponding plurality of nanosheet channel layers; and depositing a plurality of oxide layers in each of the plurality of openings, wherein the N-channel metal-oxide-semiconductor (NMOS) transistor is formed on a top surface of a middle dielectric isolation layer on a top surface of a P-channel metal-oxide-semiconductor (PMOS) transistor on a top surface of a substrate.

Further embodiments are directed to complementary field-effect transistor (CFET) devices. In one or more embodiments, a complementary field-effect transistor (CFET) device comprises: a vertically stacked superlattice structure on a substrate, the vertically stacked superlattice structure comprising a P-channel metal-oxide-semiconductor (PMOS) transistor on a top surface of the substrate, a middle dielectric isolation layer on a top surface of the PMOS transistor, and a N-channel metal-oxide-semiconductor (NMOS) transistor on a top surface of the middle dielectric isolation layer, the P-channel metal-oxide-semiconductor (PMOS) transistor comprising a plurality of silicon germanium (SiGe) channel layers and the N-channel metal-oxide-semiconductor (NMOS) transistor comprising a plurality of silicon (Si) channel layers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limited in the figures of the accompanying drawings in which like references indicate similar elements.

FIG. 1 a process flow diagram of a method of manufacturing a complementary field-effect transistor (CFET) according to one or more embodiments;

FIG. 2 illustrates a schematic cross-sectional view of a CFET device according to one or more embodiments;

FIG. 3 illustrates a schematic three-dimensional view of a CFET device according to one or more embodiments;

FIG. 4 illustrates a schematic three-dimensional view of a CFET device according to one or more embodiments;

FIG. 5 illustrates a schematic three-dimensional view of a CFET device according to one or more embodiments;

FIG. 6 illustrates a schematic three-dimensional view of a CFET device according to one or more embodiments;

FIG. 7 illustrates a schematic three-dimensional view of a CFET device according to one or more embodiments;

FIG. 8 illustrates a schematic three-dimensional view of a CFET device according to one or more embodiments;

FIG. 9 illustrates a schematic three-dimensional view of a CFET device according to one or more embodiments;

FIG. 10 illustrates a schematic three-dimensional view of a CFET device according to one or more embodiments;

FIG. 11 illustrates a schematic three-dimensional view of a CFET device according to one or more embodiments;

FIG. 12 illustrates a schematic three-dimensional view of a CFET device according to one or more embodiments;

FIG. 13 illustrates a schematic three-dimensional view of a CFET device according to one or more embodiments;

FIG. 14 illustrates a schematic three-dimensional view of a CFET device according to one or more embodiments;

FIG. 15 illustrates a schematic three-dimensional view of a CFET device according to one or more embodiments;

FIG. 16 illustrates a schematic three-dimensional view of a CFET device according to one or more embodiments;

FIG. 17 illustrates a schematic three-dimensional view of a CFET device according to one or more embodiments;

FIG. 18 illustrates a schematic three-dimensional view of a CFET device according to one or more embodiments;

FIG. 19 illustrates a schematic three-dimensional view of a CFET device according to one or more embodiments;

FIG. 20 illustrates a schematic three-dimensional view of a CFET device according to one or more embodiments;

FIG. 21 illustrates a schematic three-dimensional view of a CFET device according to one or more embodiments;

FIG. 22 illustrates a schematic three-dimensional view of a CFET device according to one or more embodiments;

FIG. 23A illustrates a schematic three-dimensional view of a CFET device according to one or more embodiments; and

FIG. 23B illustrates an enlarged cross-section schematic view of the CFET device of FIG. 23A.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate, such as a semiconductor substrate, and exhibit a doping profile suitable for a particular application. The gate is positioned over the channel region and includes a gate dielectric interposed between a gate electrode and the channel region in the semiconductor substrate.

As used herein, the term “field effect transistor” or “FET” refers to a transistor that uses an electric field to control the electrical behavior of the device. Field effect transistors are voltage-controlled devices where their current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated Is and current entering the channel at the drain (D) is designated ID. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET) and is used in integrated circuits and high-speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or NMOS FET, then the source and drain are n+ regions and the body is a p-type substrate region. If the MOSFET is a p-channel or PMOS FET, then the source and drain are p+ regions and the body is an n-type substrate region. The source is so named because it is the source of the charge carriers (electrons for n-channel, holes for p-channel) that flow through the channel; similarly, the drain is where the charge carriers leave the channel.

A NMOS FET is made up of an n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode, and saturation. Circuits with NMOS logic gates dissipate static power when the circuit is idling, since DC current flows through the logic gate when the output is low.

A PMOS FET is made up of a p-type source and drain and an n-type substrate. When a positive voltage is applied between the source and the gate (negative voltage between gate and source), a p-type channel is formed between the source and the drain with opposite polarities. A current is carried by holes from source to the drain through an induced p-type channel. A high voltage on the gate will cause a PMOS not to conduct, while a low voltage on the gate will cause it to conduct. Logic gates and other digital devices implemented using PMOS are said to have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS is considered to be faster than PMOS, since the carriers in NMOS, which are electrons, travel twice as fast as holes, which are the carriers in PMOS. But PMOS devices are more immune to noise than NMOS devices. Furthermore, NMOS integrated circuits would be smaller than PMOS integrated circuits (that give the same functionality), since the NMOS can provide one-half of the impedance provided by a PMOS (which has the same geometry and operating conditions).

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nanoslabs or nanosheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

One example of GAA technology is complementary field-effect transistor (CFET). As used herein, the term “complementary field-effect transistor (CFET)” refers to a transistor that includes a “N-channel metal-oxide-semiconductor (NMOS) FET” and “P-channel metal-oxide-semiconductor (PMOS) FET” vertically stacked on top of each other. Each of the NMOS FET devices and the PMOS FET devices that form the CFET are GAA transistors or hGAA transistors. CFETs have increased on-chip device density and reduced area consumption compared to GAA transistors. When stacking NMOS FETs and PMOS FETs in a monolithic manner, the n and p superlattice (e.g., the NMOS FET or PMOS FET, respectively) are deposited sequentially with a middle sacrificial layer that is selectively removed and replaced with a middle dielectric isolation (MDI) layer during processing. The MDI layer serves to electrically isolate the lower-level GAA from the upper-level GAA.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

Without intending to be bound by theory, it is thought that relaxation in a vertically stacked superlattice structure comprising one or more hGAAs causes defects in nanosheet channel layers within the structure. Embodiments of the present disclosure advantageously provide transistors which comprise a fully strained vertically stacked superlattice structure having nanosheet channel layers that are free or substantially free of defects. In some embodiments, the presence of defects in the nanosheet channel layers are determined by a reciprocal space mapping (RSM) method. Without intending to be bound by theory, an RSM method is an x-ray diffraction method of collecting diffraction data of the vertically stacked superlattice structure in which the presence of defects may be observed. As used herein, the term “substantially free” means that the nanosheet channel layers are substantially free of defects as determined by an RSM method.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

Embodiments of the disclosure generally relate to the field of electronic device manufacturing, and in particular, to transistors. More particularly, embodiments of the disclosure are directed to CFETs and methods of manufacturing CFETs. The devices and processes are described using this context, though the skilled artisan will recognize that the disclosed devices and processes are not limited to the illustrated applications.

One of the challenges relating to integration of CFET technology is a negative bias temperature instability (NBTI) issue that affects the NMOS device due to the diffusion of germanium (Ge) into the silicon (Si) channel during high thermal budget processes, such as the epitaxial (epi) process. Additionally, the PMOS device lacks a mobility booster, resulting in a performance gap when compared to the NMOS device (mainly due to Si orientation setup at <100>). Advantageously, in one or more embodiments, provided is a method of manufacturing a CFET that prevents germanium (Ge) diffusion in the NMOS device resulting in improved negative bias temperature (NBTI). Additionally, one or more embodiments advantageous provides a method of manufacturing a CFET that allows the use of a silicon germanium (SiGe) channel to boost the performance of the PMOS device.

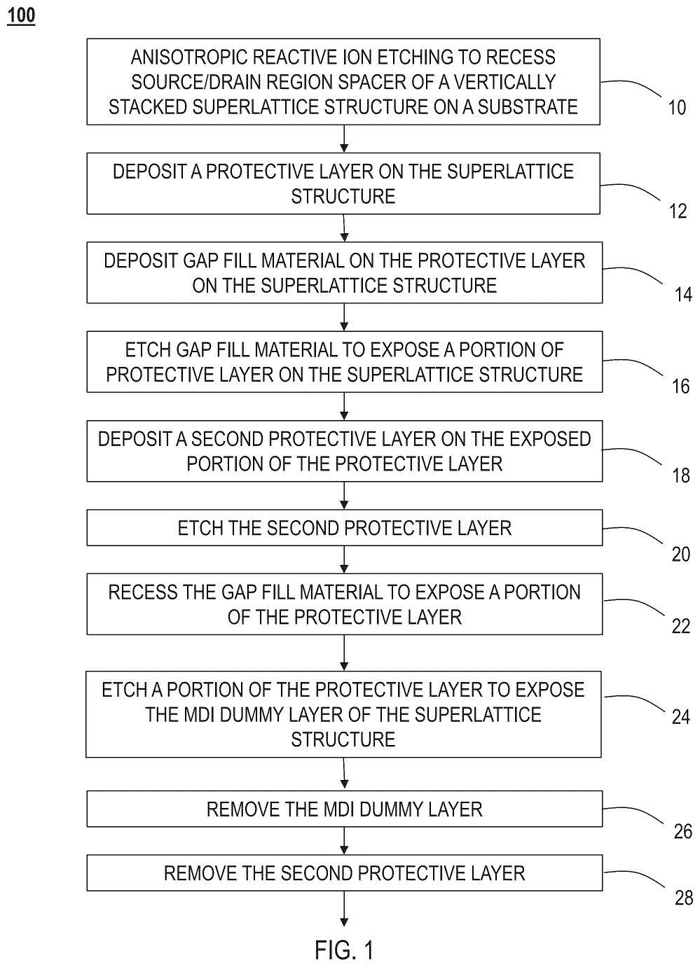

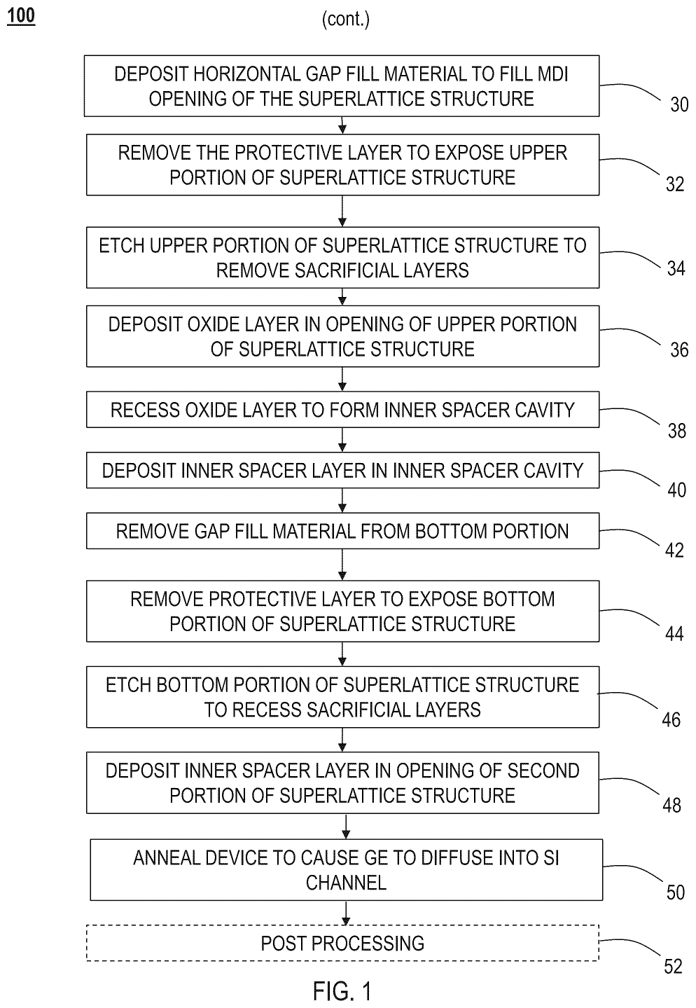

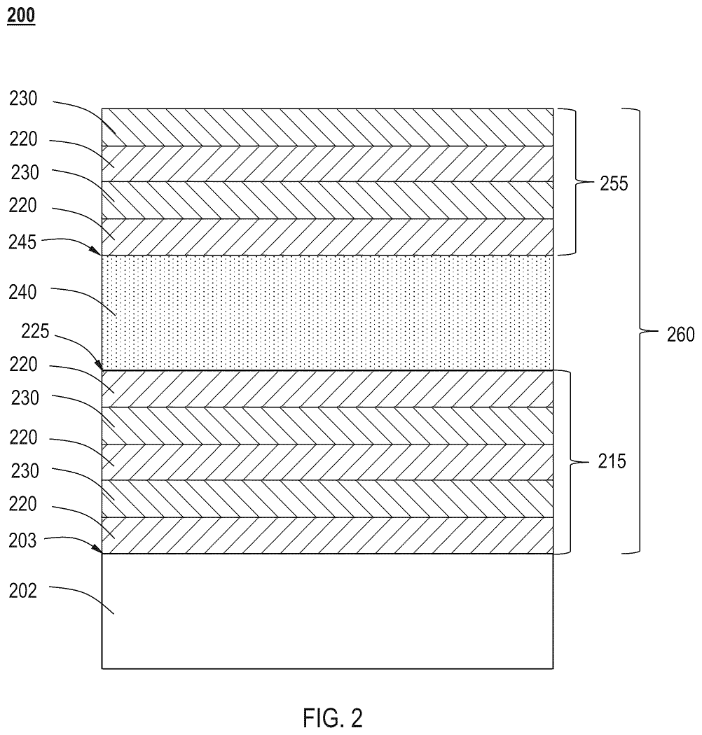

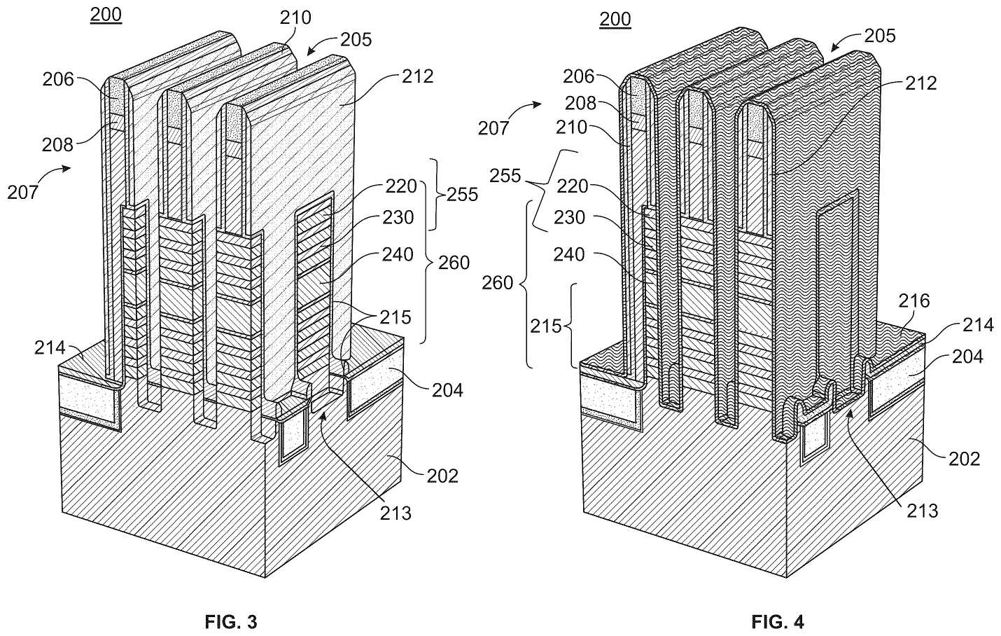

FIG. 1 illustrates a process flow diagram of a method 100 of manufacturing a CFET. FIG. 2 illustrates a schematic cross-section view of a CFET device. FIGS. 3-23B illustrate three-dimensional views of an electronic device (e.g., a transistor such as CFET 200) according to one or more embodiments. The CFET 200 shown in FIGS. 3-23B may be manufactured by the method 100 illustrated in FIG. 1.

FIG. 2 illustrates a schematic cross-sectional view of the CFET 200 having a vertically stacked superlattice structure 260 on a substrate 202. The substrate 202 has a top surface 203. The substrate 202 can be any suitable substrate material. In one or more embodiments, the substrate 202 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the substrate 202 comprises one or more of silicon (Si), germanium (Ge), gallium (Ga), arsenic (As), indium (In), phosphorus (P), or selenium (Se). Although a few examples of materials from which the substrate 202 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In one or more embodiments, the substrate 202 is a p-type or n-type substrate. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

In one or more embodiments, the vertically stacked superlattice structure 260 comprises one or more horizontal gate-all-around (hGAA) structures 215, 255 on the substrate 202. In some embodiments, the vertically stacked superlattice structure 260 comprises a first or lower horizontal gate-all-around (hGAA) structure 215 on the substrate 202. In some embodiments, the vertically stacked superlattice structure 260 comprises a first or lower horizontal gate-all-around (hGAA) structure 215 on the top surface 203 of the substrate 202. In one or more embodiments, the first or lower horizontal gate-all-around (hGAA) structure 215 is a P-channel metal-oxide-semiconductor (PMOS) transistor.

In some embodiments, the vertically stacked superlattice structure comprises a second or upper horizontal gate-all-around (hGAA) structure 255. In one or more embodiments, the second or upper horizontal gate-all-around (hGAA) structure 255 is a N-channel metal-oxide-semiconductor (NMOS) transistor.

Without intending to be bound by any particular theory of operation, the first or lower hGAA 215 and the second or upper hGAA 255 may independently comprise the same structure having the same layers. In one or more illustrated embodiments, the vertically stacked superlattice structure 260 comprises the first hGAA structure 215 on the top surface 203 of the substrate 202, a middle dielectric isolation (MDI) dummy layer 240 on a top surface 225 of the first hGAA structure 215, and the second hGAA structure 255 on a top surface 245 of the MDI dummy layer 240.

In some embodiments, each of the first hGAA 215 and the second hGAA 255 comprise alternating layers of nanosheet channel layer 230 and nanosheet release layer 220. In some embodiments, the plurality of nanosheet release layers 220 and the plurality of nanosheet channel layers 230 can comprise any number of lattice matched material pairs suitable for forming the vertically stacked superlattice structure 260. In some embodiments, each of the first hGAA 215 and the second hGAA 255 have in a range of from 1 to 5 pairs of alternating layers of nanosheet channel layers 230 and nanosheet release layers 220.

The nanosheet release layers 220 may have any suitable thickness. In one or more embodiments, each nanosheet release layer 220 has a thickness in a range of from 5 nm to 15 nm. The nanosheet channel layers 230 may have any suitable thickness. In one or more embodiments, each nanosheet channel layer 230 has a thickness in a range of from 5 nm to 15 nm.

In some embodiments, each of the nanosheet channel layers 230 independently comprises silicon (Si). In some embodiments, each of the nanosheet release layers 220 independently comprises silicon germanium (SiGe).

In one or more embodiments, the MDI dummy layer 240 is formed between the first or lower hGAA 215 and the second or upper hGAA 255. In one or more embodiments, the MDI dummy layer 240 is selectively removed and replaced with a middle dielectric isolation (MDI) layer gap fill material 266 during processing. The MDI dummy layer 240 serves to electrically isolate the source/drain regions of the first or lower GAA 215 from the source/drain regions of the second or upper GAA 255. The MDI dummy layer 240 may comprise any suitable material. In one or more embodiments, the MDI dummy layer 240 comprises silicon germanium (SiGe). In one or more embodiments, the MDI dummy layer 240 comprises silicon germanium (SiGe) having a higher concentration of germanium (Ge) than the SiGe of the nanosheet release layers 220. In subsequent processing, as detailed below, the MDI dummy layer 240 is replaced with the MDI layer gap fill material 266. The MDI layer gap fill material 266 may comprise any suitable material known to the skilled artisan. In one or more embodiments, the MDI layer gap fill material 266 comprises a dielectric material, as detailed below.

In one or more embodiments, the MDI dummy layer 240 may have any suitable thickness. In some embodiments, the MDI dummy layer 240 has a thickness in a range of from 15 nm to 90 nm, including a range of from 15 nm to 80, a range of from 20 nm to 75 nm, a range of from 15 nm to 60 nm, a range of from 15 nm to 50 nm, a range of from 15 nm to 75 nm, and a range of from 20 nm to 50 nm. In some embodiments, increasing the thickness of the MDI dummy layer 240 to greater than 40 nm increases the etch selectivity between the MDI dummy layer 240 and the nanosheet release layer 220.

As recognized by one of skill in the art, during subsequent processing, the MDI dummy layer 240 may be removed and replaced with the MDI layer gap fill material 266. In one or more embodiments, the MDI dummy layer 240 is selectively removed. Selectively removing the sacrificial layer may be performed by any suitable means known to the skilled artisan. In some embodiments, selectively removing the sacrificial layer comprises an etch process that removes the sacrificial layer and does not remove the nanosheet release layers 220. In some embodiments, the etch process is an isotropic etch process.

In one or more unillustrated embodiments, the vertically stacked superlattice structure 260 includes a plurality of vertically extending trenches and a plurality of horizontally extending trenches. In one or more embodiments, the plurality of vertically extending trenches extend vertically from a top surface of the second or upper hGAA 255, through the MDI dummy layer 240, and through the first or lower hGAA 215 to the top surface 203 of the substrate 202. In one or more embodiments, the plurality of horizontally extending trenches extend horizontally through the plurality of nanosheets in the second or upper hGAA 255, and through the plurality of nanosheets in the first or lower hGAA 215.

Embodiments of the present disclosure advantageously provide methods of manufacturing electronic devices (e.g., CFETs) that prevent germanium (Ge) diffusion in the NMOS device, improve NBTI, and allows the use of a silicon germanium (SiGe) channel to boost the performance of the PMOS device. While the Figures illustrate a CFET device, one of skill in the art recognizes that the methods employed herein can be applied to a gate-all-around (GAA) device or a nanosheet device as well.

FIG. 1 illustrates a process flow diagram of a method 100 of manufacturing a complementary field-effect transistor (CFET). The method 100 comprises, at operation 10, anisotropic reaction ion etching (RIE) to recess the source/drain region spacers of the vertically stacked superlattice structure on a substrate. At operation 12, the method 100 includes depositing a first protective layer. At operation 14, the method 100 includes depositing a gap fill material on the first protective layer. At operation 16, the method 100 includes etching the gap fill material to expose a portion of the first protective layer on the second or upper hGAA. At operation 18, the method 100 includes depositing a second protective layer on an exposed portion of the first protective layer. At operation 20, the method 100 includes etching the vertically stacked superlattice structure to remove the second protective layer from the top surface of the gap fill material. At operation 22, the method 100 includes recessing the gap fill material to expose a portion of the first protective layer in the MDI region of the superlattice structure. At operation 24, the method 100 includes etching a portion of the first protective layer to expose the MDI layer of the superlattice structure. At operation 26, the method 100 includes removing the MDI layer to form an MDI opening. At operation 28, the method 100 includes removing the second protective layer. At operation 30, the method 100 includes depositing a gap fill material horizontally in the MDI opening. At operation 32, the method 100 includes removing the first protective layer from the second or upper hGAA of the superlattice structure. At operation 34, the method 100 includes etching the vertically stacked superlattice structure to remove the sacrificial layers from the second or upper hGAA. At operation 36, the method 100 includes depositing an oxide layer in the openings of the second or upper hGAA. At operation 38, the method 100 includes recessing the oxide layer to form an inner spacer cavity. At operation 40, the method 100 includes depositing an inner spacer layer in the inner spacer cavity. At operation 42, the method 100 includes removing the gap fill material from the first or lower hGAA. At operation 44, the method 100 includes removing the first protective layer to expose the alternating layers of the first or lower hGAA. At operation 46, the method 100 includes recessing the sacrificial layers in the first or lower hGAA to form inner spacer cavities. At operation 48, the method 100 includes depositing an inner spacer layer in the inner spacer cavities of the first or lower hGAA. At operation 50, the method 100 includes annealing the substrate at a temperature of less than or equal to 1000° C. to drive germanium (Ge) atoms into the silicon channel.

In one or more embodiments, the method 100 consists essentially of operations 10, 12, 14, 16, 18, 20, 22, 24, 26, 28, 30, 32, 34, 36, 38, 40, 42, 44, 46, 48, and 50. In one or more embodiments, the method 100 consists of operations 10, 12, 14, 16, 18, 20, 22, 24, 26, 28, 30, 32, 34, 36, 38, 40, 42, 44, 46, 48, and 50.

FIGS. 3-23B illustrate three-dimensional views of an electronic device (e.g., a transistor such as complementary field-effect transistor (CFET) 200) according to one or more embodiments. The CFET 200 shown in FIGS. 3-23B may be manufactured by the method 100 illustrated in FIG. 1.

As illustrated in FIG. 3, a complementary field-effect transistor (CFET) device 200 includes a first or lower hGAA 215 formed on a substrate 202, as described above. The substrate 202 may also include one or more shallow trench isolation (STI) oxide layers 204. In some embodiments a shallow trench isolation (STI) protective layer 214 may be formed on a top surface of the shallow trench isolation (STI) oxide layer 204. A middle dielectric isolation layer 240 is formed on the top surface of the first or lower hGAA 215. A second or upper hGAA 255 is formed on the top surface of the middle dielectric isolation layer 240. A gate region 207 including a gate material 208 and a gate hard mask layer 206 is formed on the top surface of the second or upper hGAA 255. In one or more embodiments, a first gate spacer layer 210 and a second gate spacer layer 212 are formed over the gate region, the second or upper hGAA 255, the middle dielectric isolation layer 240, and the first or lower hGAA 215.

With reference to FIGS. 1 and 3, in some embodiments, at operation 10, an anisotropic reactive ion etching (RIE) process is used to recess back the source/drain region 213 spacer layers 210, 212 to expose a portion 211 of the vertically stacked superlattice structure 260. The anisotropic reactive ion etching (RIE) process may be any suitable anisotropic reactive ion etching (RIE) technique known to the skilled artisan. In some embodiments, at operation 10, the MDI dummy layer 240, and the first hGAA structure 215 and the second hGAA structure 255 are exposed in the source/drain region 213.

Referring to FIGS. 1 and 4, in some embodiments, at operation 12, a first protective layer 216 is formed on the device 200 and on the top surface of the substrate 202. The first protective layer 216 may be formed by any suitable deposition technique known to the skilled artisan, such as, but not limited to, ALD, CVD, PVD, MBE, MOCVD, spin-on, or other protective layer deposition techniques known to the skilled artisan. In some embodiments, at operation 12, the first protective layer 216 is conformally deposited on the device 200 by ALD.

In one or more embodiments, the first protective layer 216 may comprise any suitable material known to the skilled artisan. In some embodiments, the first protective layer 216 comprises one or more of silicon (Si), silicon oxide (SiOx), silicon nitride (SIN), titanium nitride (TiN), aluminum oxide (AIOx), tantalum nitride (TaN), silicon carbide (SiC), silicon carbonitride (SiCN), silicon carbooxynitride (SiCON), and the like.

In one or more embodiments, the first protective layer 216 may have any suitable thickness. In some embodiments, the first protective layer 216 has a thickness in a range of from >0 Å to 50 Å, including in a range of from 5 Å to 30 Å.

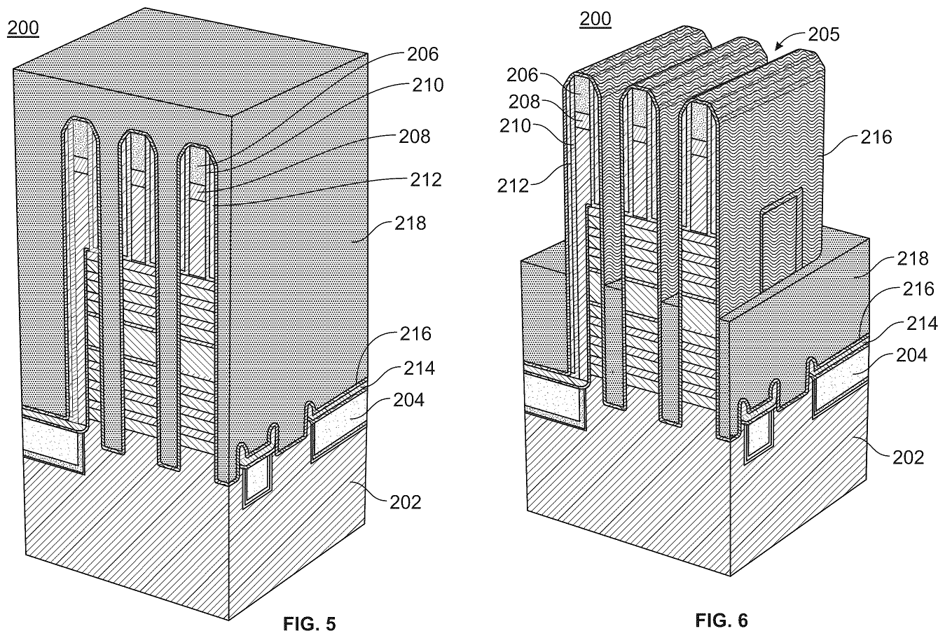

Referring to FIGS. 1 and 5, in one or more embodiments, at operation 14, a gap fill material 218 is deposited on the device to fill the source/drain region 213. The gap fill material 218 may be deposited by any suitable gap fill process known to the skilled artisan. In one or more embodiments, the gap fill material 218 is deposited by a bottom-up gap fill process that fills the source/drain region 213 from the bottom and sides. As illustrated in FIG. 5, a gap fill material 218 is deposited as a gap fill on a substrate 202 having at least one feature (e.g., source/drain region 213) including a bottom and at least on sidewall surface. In one or more embodiments, the gap fill material 218 is deposited in a bottom-up manner in the at least one feature to fill the at least one feature with the gap fill material 218.

In one or more embodiments, the gap fill material 218 may comprise any suitable gap fill material known to the skilled artisan. In one or more embodiments, the gap fill material 218 comprises one or more of carbon (C), silicon oxide (SiOx), silicon carbooxynitride (SiCON), and the like. In one or more embodiments, the gap fill material 218 is deposited to provide a seamless, or substantially seamless, gap fill. In one or more embodiments, the gap fill material 218 is etch selective to the first protective layer 216.

Referring to FIGS. 1 and 6, in one or more embodiments, at operation 16, the gap fill material 218 is etched back from the second or upper hGAA 255 and the gate region 207 to expose the first protective layer 216 on second or upper hGAA 255 and on the gate region 207. In one or more embodiments, the gap fill material 218 remains on the first or lower hGAA 215 of the device 200. The etch process may comprise any suitable etch process known to the skilled artisan. In one or more embodiments, the etch process comprises one or more of an isotropic etch process or an anisotropic etch process.

The etching process of operation 16 can be any suitable etching process known to the skilled artisan. In some embodiments, the etching process comprises a wet etch process or a dry etch process. In some embodiments, the etching process comprises a wet etch process. In some embodiments, the wet etch process includes a pre-clean process.

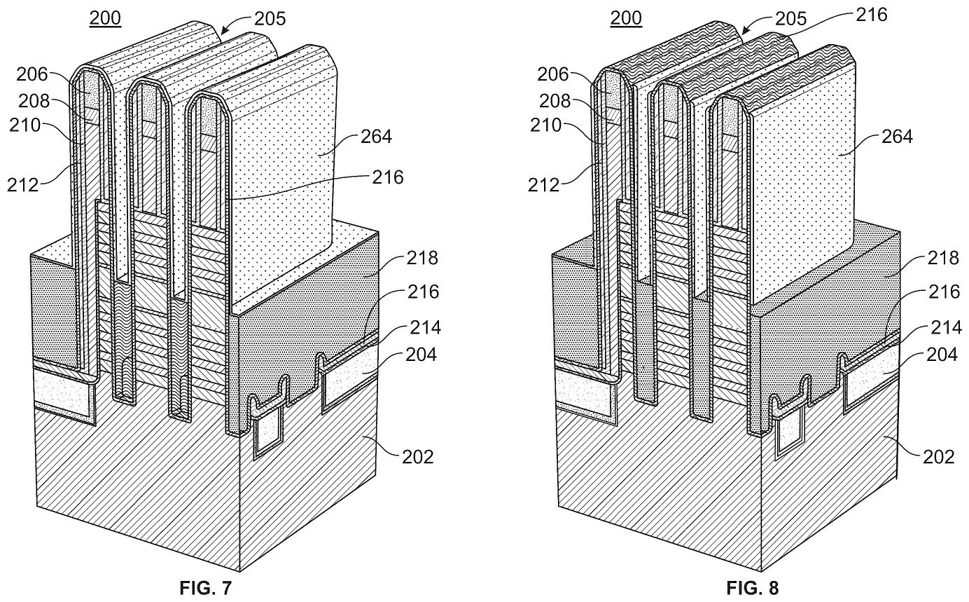

Referring to FIGS. 1 and 7, in one or more embodiments, at operation 18, a second protective layer 264 is conformally deposited on the second or upper hGAA 255 and on the gate region 207 of the device 200. In one or more embodiments, the second protective layer 264 forms on a top surface of the gap fill material 218. The second protective layer 264 may be deposited by any suitable deposition technique known to the skilled artisan including, but not limited to, ALD, CVD, PVD, MBE, MOCVD, spin-on, or other protective layer deposition techniques known to the skilled artisan. In one or more embodiments, the second protective layer 264 may comprise any suitable material known to the skilled artisan. In some embodiments, the second protective layer 264 comprises one or more of silicon (Si), silicon oxide (SiOx), silicon nitride (SiN), titanium nitride (TiN), aluminum oxide (AIOx), tantalum nitride (TaN), silicon carbide (SiC), silicon carbonitride (SiCN), silicon carbooxynitride (SiCON), and the like.

In one or more embodiments, the second protective layer 264 may have any suitable thickness. In some embodiments, the second protective layer 264 has a thickness in a range of from >0 Å to 50 Å, including in a range of from 5 Å to 30 Å.

Referring to FIGS. 1 and 8, in one or more embodiments, at operation 20, an etch process is performed to remove the second protective layer from a top surface of the gate region 207 of the device to expose the first protective layer 216, and to remove the second protective layer 264 from the top surface of the gap fill material 218, exposing the top surface of the gap fill material 218. The etch process may comprise any suitable etch process known to the skilled artisan. In one or more embodiments, the etch process comprises an anisotropic etch process.

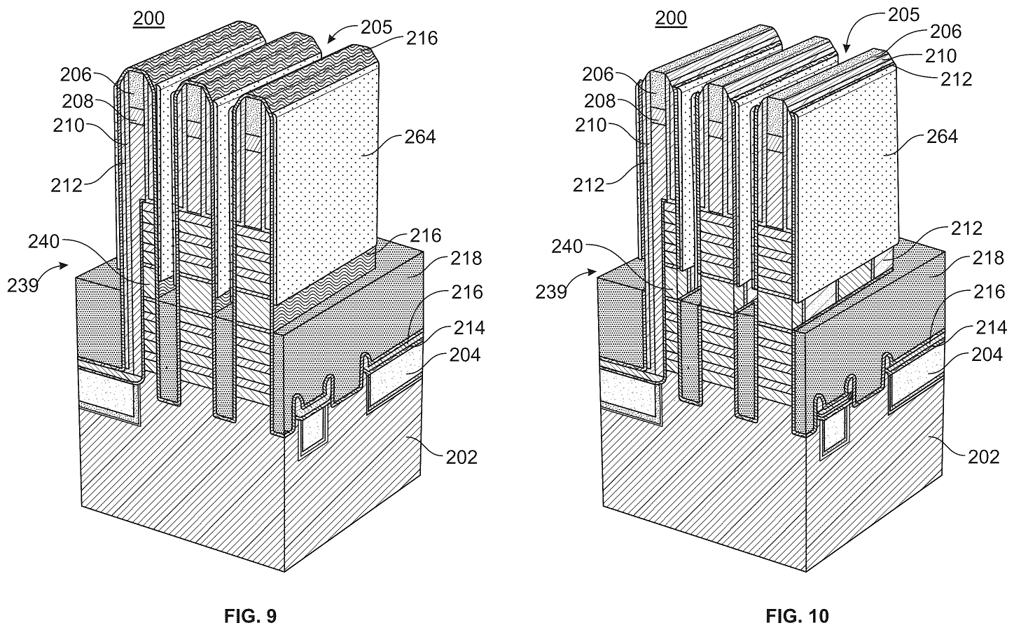

Referring to FIGS. 1 and 9, in one or more embodiments, at operation 22, an etch process is performed to recess the gap fill material 218 from the MDI region 239, exposing the first protective liner 216 in the MDI region 239. The etch process is selective to the gap fill material 218 over the second protective layer 264 and the first protective layer 216, such that the second protective layer 264 remains on the second or upper hGAA 255. The etch process may comprise any suitable etch process known to the skilled artisan. In one or more embodiments, the etch process comprises one or more of an isotropic etch process or an anisotropic etch process.

Referring to FIGS. 1 and 10, in one or more embodiments, at operation 24, the first protective layer 216 is removed from the MDI region 239 of the device 200 to expose the MDI dummy layer 240 and the gate spacer materials 210, 212. The first protective layer 216 may be removed by any suitable etch process known to the skilled artisan. In one or more embodiments, the etch process comprises an isotropic etch process.

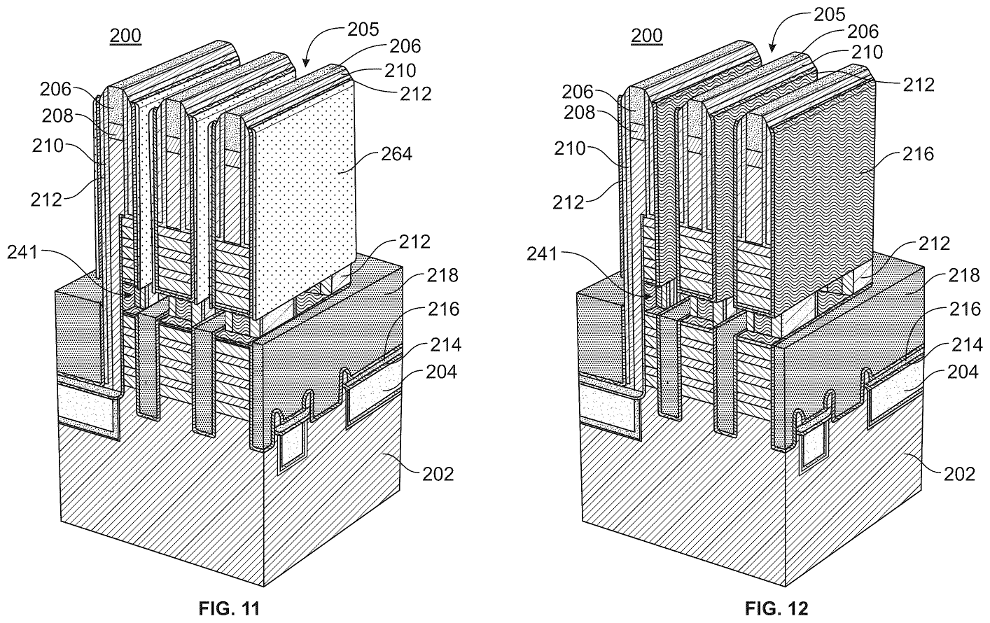

Referring to FIGS. 1 and 11, in one or more embodiments, at operation 26, the MDI dummy layer 240 is removed to form an MDI opening 241 adjacent to the gate spacer materials 210, 212 in the MDI region 239 of the device 200. The MDI dummy layer 240 may be removed by any suitable etch process known to the skilled artisan. In one or more embodiments, the etch process comprises an isotropic etch process.

Referring to FIGS. 1 and 12, in one or more embodiments, at operation 28, the second protective layer 264 is removed from the second or upper hGAA 255 and from the gate region 207 to expose the underlying first protective layer 216. The second protective layer 264 may be removed by any suitable etch process known to the skilled artisan. In one or more embodiments, the etch process comprises an isotropic etch process.

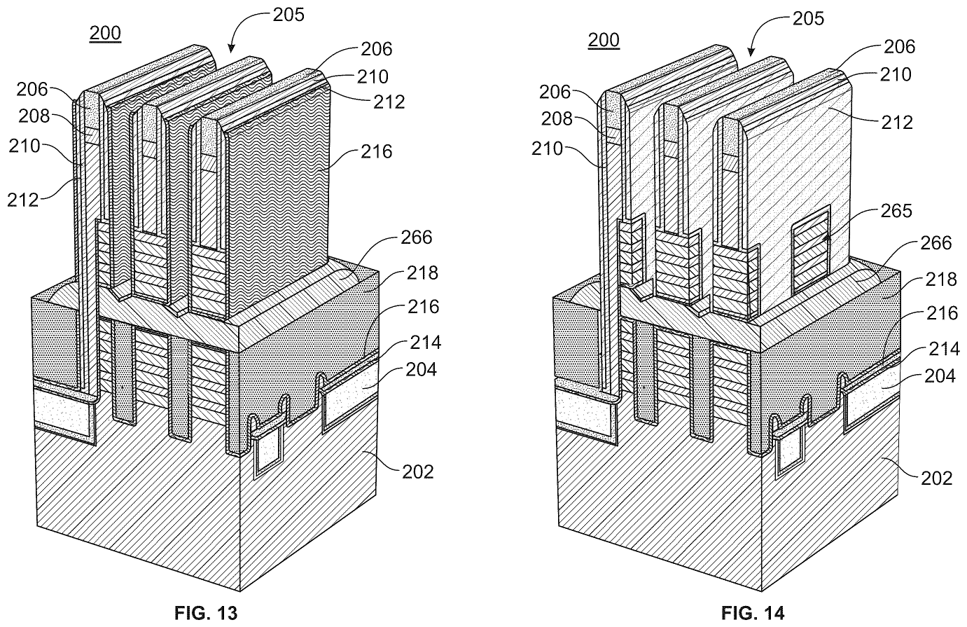

Referring to FIGS. 1 and 13, in one or more embodiments, at operation 30, a gap fill material 266 is deposited horizontally in the MDI opening 241 to fill the MDI opening 241. In one or more embodiments, the gap fill material 266 may comprise any suitable material known to the skilled artisan. In one or more embodiments, the gap fill material 266 comprises a dielectric material. As used herein, the term “dielectric material” refers to an electrical insulator that can be polarized in an electric field. In some embodiments, the gap fill material 266 comprises one or more of silicon, silicon oxide, silicon nitride, silicon carbide, and low-K dielectrics. As used herein, terms such as “silicon oxide” and “silicon nitride” refer to materials comprising silicon and oxygen or silicon and nitrogen. “Silicon oxide” and “silicon nitride” should not be understood to imply any stoichiometric ratio. Stated differently, a dielectric material comprising silicon oxide or silicon nitride may be stoichiometric or non-stoichiometric, silicon-rich, or silicon-poor. In some embodiments, the gap fill material 266 comprises a low-K material. In one or more embodiments, the gap fill material 266 comprises one or more or low-K silicon carbooxynitride (SiCON), silicon oxycarbide (SiCO), or oxide. Referring to FIGS. 1 and 14, in one or more embodiments, at operation 32, the first protective layer 216 is removed from the second or upper hGAA 255 and from the gate region 207 to expose the gate spacer materials 210, 212. In one or more embodiments, the alternating layers of nanosheet channel layers 230 and nanosheet release layers 220 of the second or upper hGAA 255 are exposed in a region 265. The first protective layer 216 may be removed by any suitable etch process known to the skilled artisan. In one or more embodiments, the etch process comprises an isotropic etch process.

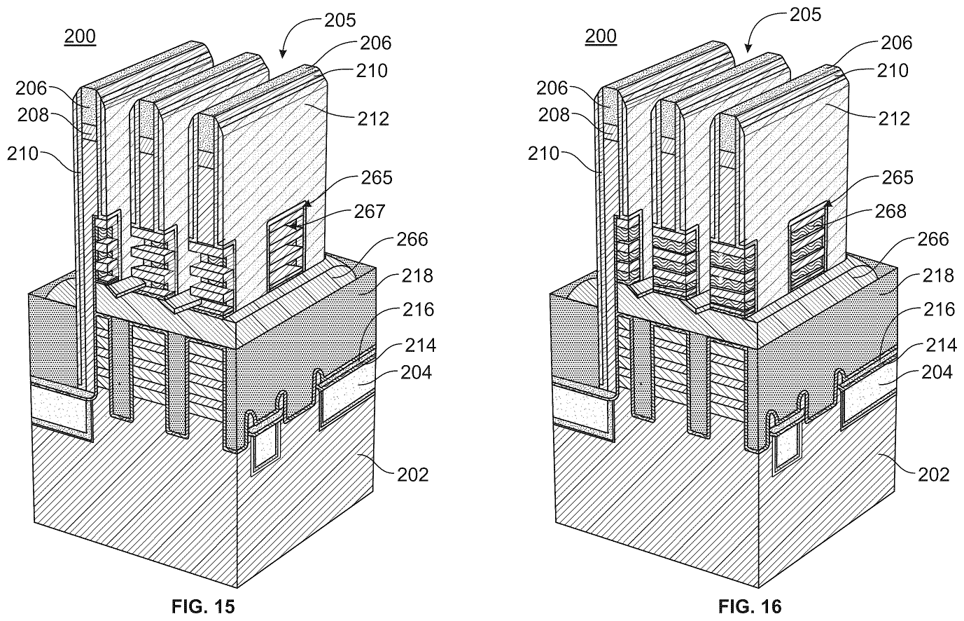

Referring to FIGS. 1 and 15, in one or more embodiments, at operation 34, the nanosheet release layers 220 are removed from the second or upper hGAA 255 to form an opening 267 adjacent the plurality of nanosheet channel layers 230 of the second or upper hGAA 255. The nanosheet release layers 220 may be removed by any suitable etch process known to the skilled artisan. In one or more embodiments, the etch process comprises an isotropic etch process.

Referring to FIGS. 1 and 16, in one or more embodiments, at operation 36, an oxide layer 268 is deposited into the opening 267 formed by the removal of the nanosheet release layers 220 from the second or upper hGAA 255. The oxide layer 268 may be deposited by any suitable deposition technique known to the skilled artisan including, but not limited to, ALD, CVD, PVD, MBE, MOCVD, spin-on, or other protective layer deposition techniques known to the skilled artisan. In some embodiments, the oxide layer 268 is deposited by atomic layer deposition (ALD) gap fill followed by trim back.

Without intending to be bound by theory, it is thought that the oxide layer 268 will prevent germanium (Ge) atoms from diffusing into the nanosheet channel layers 230 of the second or upper hGAA 255 during subsequent annealing of the device 200. In other words, the presence of the oxide layer 268 enables a higher thermal budget for the NMOS device (e.g., the second or upper hGAA 255) compared to the PMOS device (e.g., the first or lower hGAA 215) because germanium (Ge) atoms are prevented from diffusing into the silicon channel of the nanosheet channel layers 230.

In one or more embodiments, the oxide layer 268 may comprise any suitable material known to the skilled artisan. In some embodiments, the oxide layer 268 comprises silicon oxide (SiOx), and the like.

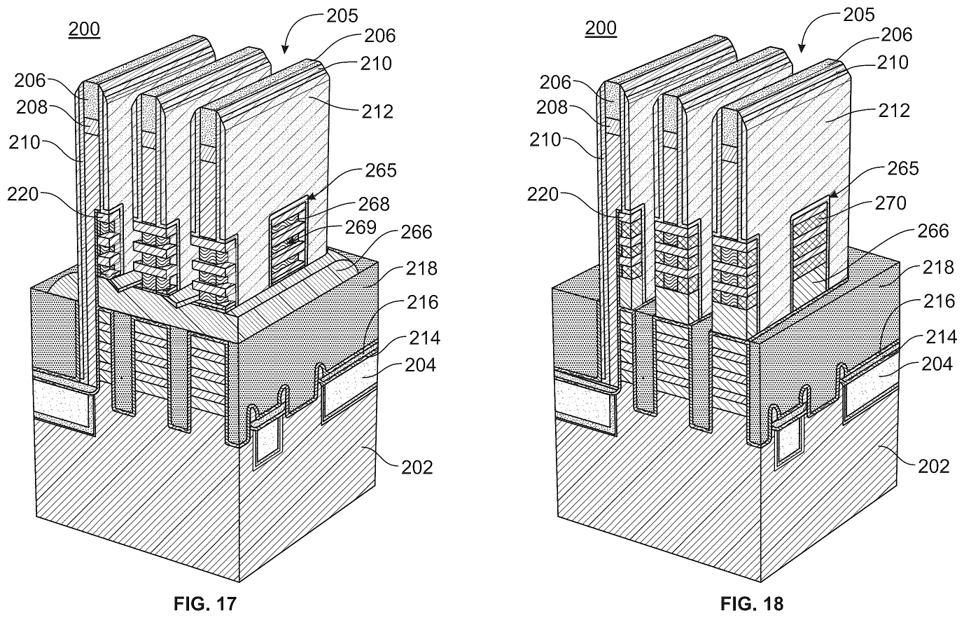

Referring to FIGS. 1 and 17, in one or more embodiments, at operation 38, the oxide layer 268 is recessed to form an inner spacer cavity 269 in the second or upper hGAA 255. The oxide layer 268 may be recessed by any suitable etch process known to the skilled artisan. In one or more embodiments, the etch process comprises an isotropic etch process.

Referring to FIGS. 1 and 18, in one or more embodiments, at operation 40, an inner spacer layer 270 is deposited in the inner spacer cavity 269 adjacent to the plurality of nanosheet channel layers 230 of the second or upper hGAA 255. The inner spacer layer 270 may be deposited by any suitable deposition technique known to the skilled artisan including, but not limited to, ALD, CVD, PVD, MBE, MOCVD, spin-on, or other protective layer deposition techniques known to the skilled artisan. In some embodiments, the inner spacer layer 270 is deposited by atomic layer deposition (ALD) gap fill or horizontal gap fill followed by planarization or trim back.

In one or more embodiments, the inner spacer layer 270 may comprise any suitable material known to the skilled artisan. In some embodiments, the inner spacer layer 270 comprises any suitable dielectric material. In some embodiments, the inner spacer layer 270 comprises one or more of silicon, silicon oxide, silicon nitride, silicon carbide, and low-K dielectrics. In some embodiments, the inner spacer layer 270 comprises a low-K material. In one or more embodiments, the inner spacer layer 270 comprises one or more or low-K silicon carbooxynitride (SiCON), silicon oxycarbide (SiCO), or oxide.

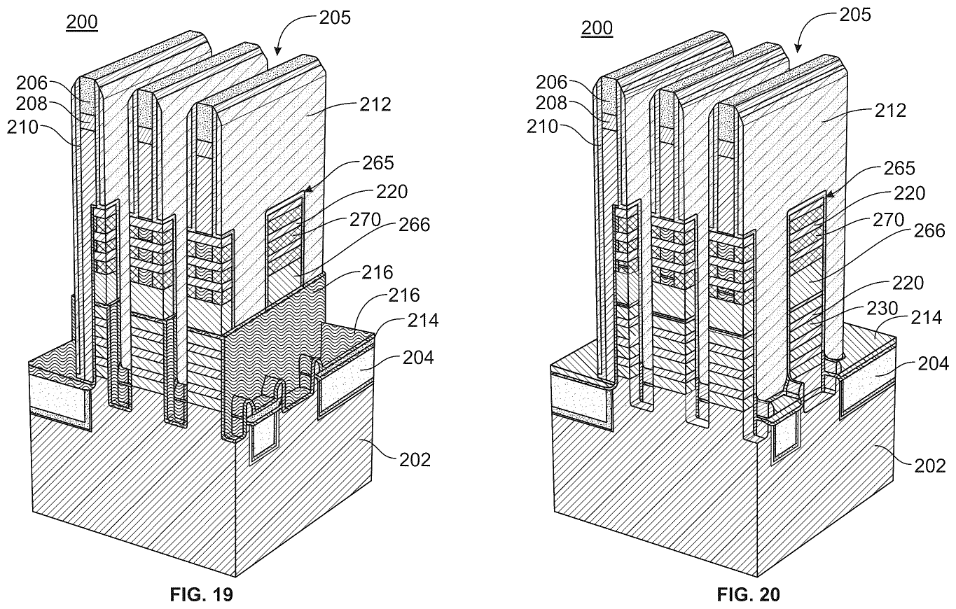

Referring to FIGS. 1 and 19, in one or more embodiments, at operation 42, the gap fill material 218 is removed from the first or lower hGAA 215 to expose the first protective layer 216 on the first or lower hGAA 215. The gap fill material 218 may be recessed by any suitable etch process known to the skilled artisan. In one or more embodiments, the etch process comprises one or more of an anisotropic etch process or an isotropic etch process.

Referring to FIGS. 1 and 20, in one or more embodiments, at operation 44, the first protective layer 216 is removed from the first or lower hGAA 215 to expose the gate spacer material 212 on both of the first or lower hGAA 215 and on the second or top hGAA 255. In one or more embodiments, the alternating layers of nanosheet channel layers 230 and nanosheet release layers 220 of the first or lower hGAA 215 are exposed in region 265. The first protective layer 216 may be removed by any suitable etch process known to the skilled artisan. In one or more embodiments, the etch process comprises one or more of an isotropic etch process.

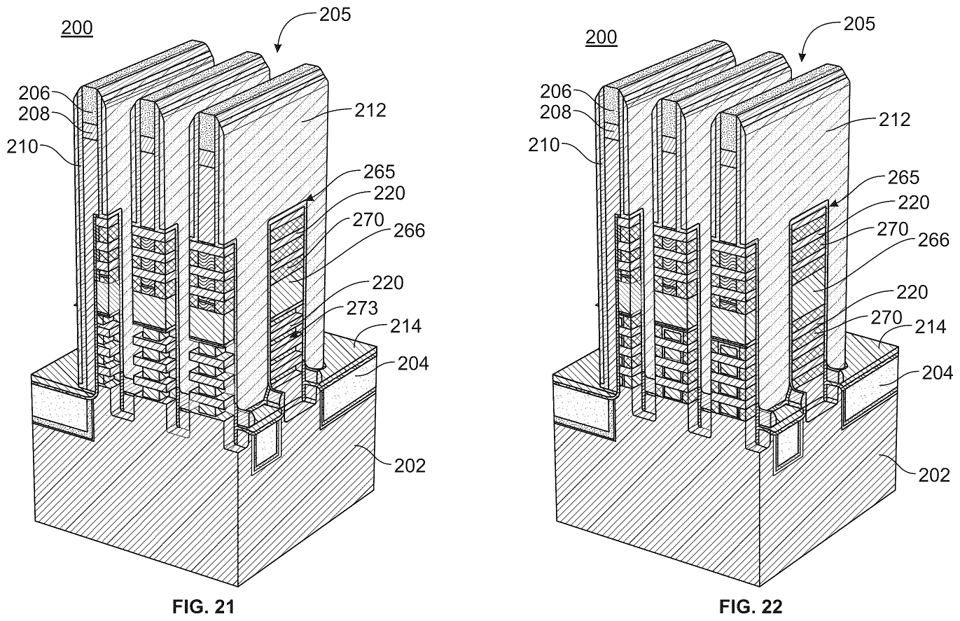

Referring to FIGS. 1 and 21, in one or more embodiments, at operation 46, the nanosheet release layers 220 of the first or lower hGAA 215 are recessed to form a recess opening 273 adjacent to the plurality of nanosheet channel layers 230 of the first or lower hGAA 215. The nanosheet release layers 220 may be recessed by any suitable etch process known to the skilled artisan. In one or more embodiments, the etch process comprises an isotropic etch process.

Referring to FIGS. 1 and 22, in one or more embodiments, at operation 48, an inner spacer layer 270 is deposited in the recess opening 273 adjacent to the plurality of nanosheet channel layers 230 of the first or lower hGAA 215. The inner spacer layer 270 may be deposited by any suitable deposition technique known to the skilled artisan including, but not limited to, ALD, CVD, PVD, MBE, MOCVD, spin-on, or other protective layer deposition techniques known to the skilled artisan. In some embodiments, the inner spacer layer 270 is deposited by atomic layer deposition (ALD) gap fill or horizontal gap fill followed by planarization or trim back. In one or more embodiments, the inner spacer layer 270 may comprise any suitable material known to the skilled artisan. In some embodiments, the inner spacer layer 270 comprises any suitable dielectric material. In some embodiments, the inner spacer layer 270 comprises one or more of silicon, silicon oxide, silicon nitride, silicon carbide, and low-K dielectrics. In some embodiments, the inner spacer layer 270 comprises a low-K material. In one or more embodiments, the inner spacer layer 270 comprises one or more or low-K silicon carbooxynitride (SiCON), silicon oxycarbide (SiCO), or silicon carbonitride (SiCN).

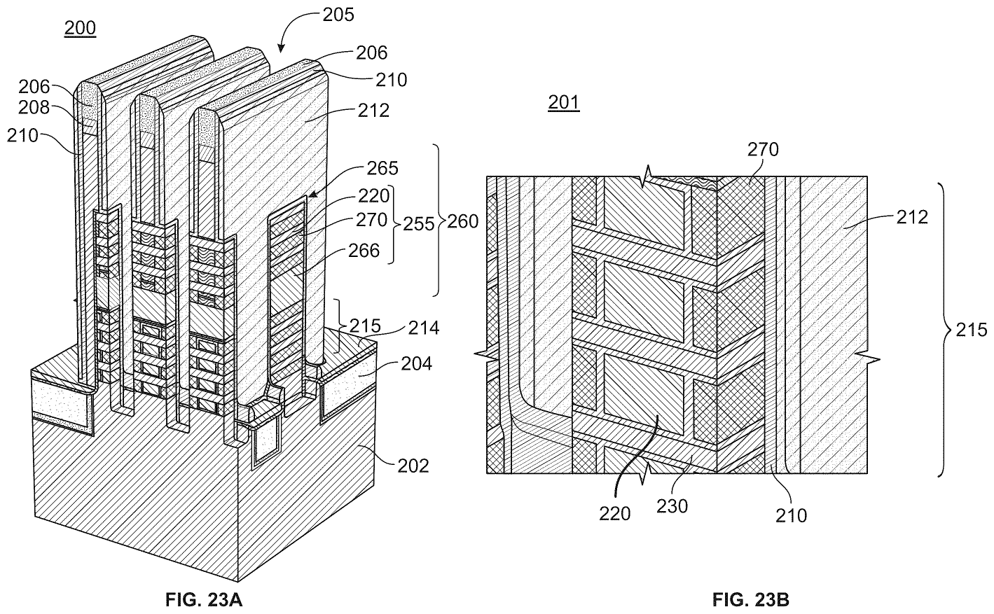

Referring to FIGS. 1 and 23A-23B, in some embodiments, at operation 50, the method 100 includes annealing the device 200 at a temperature of less than or equal to 1000° C. to drive germanium (Ge) atoms from the recessed nanosheet release layers 220 of the first or lower hGAA 215 into the adjacent nanosheet channel layers 230 of the first or lower hGAA forming a silicon germanium (SiGe) channel.

In some embodiments, at operation 50, the method 100 comprises annealing the device 200 at a temperature of less than or equal to 950° C. In some embodiments, the temperature is in a range of from 500° C. to 1000° C., including in a range of from 600°° C. to 1000° C., in a range of from 700° C. to 1000° C., in a range of from 750° C. to 950° C., or in a range of from 800° C. to 900° C.

Without intending to be bound by theory, it is thought that annealing the device 200 according to operation 50 drives an increased number of germanium (Ge) atoms from the nanosheet release layers 220 into the nanosheet channel layers 230 to form a silicon germanium (SiGe) channel in the PMOS (e.g., the first or lower hGAA), as compared to methods where annealing does not occur. In one or more embodiments, annealing the device 200 at operation 50 includes a rapid thermal process (RTP). The RTP may be any suitable process known to the skilled artisan. Without intending to be bound by theory, when, at operation 50, the method 100 comprises annealing the device 200 at a temperature of less than or equal to 1000° C. to drive germanium (Ge) atoms from the nanosheet release layers 220 into the silicon channel of the nanosheet channel layers 230.

After operation 50, the method 100 can include any post-processing operations 52 for semiconductor manufacturing known to the skilled artisan.

Further embodiments of the disclosure are directed to electronic devices having a plurality of CFET regions. In one or more embodiments, the electronic device comprises the CFET 200 formed by method 100.

Additional embodiments of the disclosure are directed to processing tools (i.e., a cluster tool) for performing the methods and the CFETs described. In one or more embodiments, the cluster tool comprises an integrated processing system such that the operations of method 100 are performed without a vacuum break. In one or more embodiments, there is a vacuum break in between at least one of the operations of method 100.

The particular arrangement of process chambers and components can be varied depending on the cluster tool and should not be taken as limiting the scope of the disclosure.

Embodiments of the disclosure are directed to a non-transitory computer readable medium. In one or more embodiments, the non-transitory computer readable medium includes instructions that, when executed by a controller of a processing chamber, causes the processing chamber to perform the operations of any of the methods described herein. In one or more embodiments, the controller causes the processing chamber to perform the operations of method 100.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of forming a complementary field-effect transistor (CFET), the method comprising:
removing a plurality of nanosheet release layers from a N-channel metal-oxide-semiconductor (NMOS) transistor to form a plurality of openings adjacent a corresponding plurality of nanosheet channel layers; and
depositing a plurality of oxide layers in each of the plurality of openings,
wherein the N-channel metal-oxide-semiconductor (NMOS) transistor is formed on a top surface of a middle dielectric isolation (MDI) dummy layer on a top surface of a P-channel metal-oxide-semiconductor (PMOS) transistor on a top surface of a substrate.

2. The method of claim 1, wherein the N-channel metal-oxide-semiconductor (NMOS) transistor comprises a superlattice structure including alternating layers of the plurality of nanosheet release layers and the corresponding plurality of nanosheet channel layers.

3. The method of claim 2 wherein the plurality of nanosheet channel layers of the N-channel metal-oxide-semiconductor (NMOS) transistor comprises silicon (Si).

4. The method of claim 2, wherein the plurality of oxide layers of the N-channel metal-oxide-semiconductor (NMOS) transistor comprise silicon oxide (SiOx).

5. The method of claim 1, further comprising removing the plurality of nanosheet release layers in the P-channel metal-oxide-semiconductor (PMOS) transistor to form a plurality of recess openings adjacent a corresponding plurality of nanosheet channel layers in the P-channel metal-oxide-semiconductor (PMOS) transistor.

6. The method of claim 5, further comprising depositing a plurality of inner spacer layers in the plurality of recess openings.

7. The method of claim 6, wherein the plurality of inner spacer layers comprises one or more of low-K silicon carbooxynitride (SiCON), silicon oxycarbide (SiCO), or oxide.

8. The method of claim 6, further comprising annealing the complementary field-effect transistor (CFET).

9. The method of claim 8, wherein annealing the complementary field-effect transistor (CFET) comprises rapid thermal processing (RTP) at a temperature of less than or equal to 1000° C.

10. The method of claim 8, wherein annealing the complementary field-effect transistor (CFET) drives germanium (Ge) atoms from the plurality of nanosheet release layers in the P-channel metal-oxide-semiconductor (PMOS) transistor into the corresponding plurality of nanosheet channel layers.

11. The method of claim 8, wherein the plurality of oxide layer prevents germanium (Ge) diffusion into plurality of channel layers in the N-channel metal-oxide-semiconductor (NMOS) transistor.

12. The method of claim 10, wherein the germanium (Ge) atoms in the plurality of nanosheet channer layers of P-channel metal-oxide-semiconductor (PMOS) transistor boosts performance of the P-channel metal-oxide-semiconductor (PMOS) transistor.

13. The method of claim 2, further comprising:
depositing a first protective layer on the N-channel metal-oxide-semiconductor (NMOS) transistor, the middle dielectric isolation (MDI) dummy layer, and the P-channel metal-oxide-semiconductor (PMOS) transistor prior to removing the plurality of nanosheet release layers from the N-channel metal-oxide-semiconductor (NMOS) transistor;
depositing a gap fill material on the first protective layer;
removing a portion of the gap fill material from the N-channel metal-oxide-semiconductor (NMOS) transistor to expose the first protective layer;
depositing a second protective layer on the exposed first protective layer on the N-channel metal-oxide-semiconductor (NMOS) transistor;
removing a portion of the second protective layer to expose a top surface of the gap fill material on the middle dielectric isolation (MDI) dummy layer and the P-channel metal-oxide-semiconductor (PMOS) transistor;
removing a portion of the gap fill material and the first protective layer to expose the middle dielectric isolation (MDI) dummy layer;
removing the middle dielectric isolation (MDI) dummy layer to form a middle dielectric isolation (MDI) layer opening; and
depositing a second gap fill material in the middle dielectric isolation (MDI) layer opening.

14. The method of claim 13, wherein the second gap fill material comprises a low-K dielectric material.

15. A complementary field-effect transistor (CFET) device comprising:
a vertically stacked superlattice structure on a substrate, the vertically stacked superlattice structure comprising a P-channel metal-oxide-semiconductor (PMOS) transistor on a top surface of the substrate, a middle dielectric isolation layer on a top surface of the PMOS transistor, and a N-channel metal-oxide-semiconductor (NMOS) transistor on a top surface of the middle dielectric isolation (MDI) layer, the P-channel metal-oxide-semiconductor (PMOS) transistor comprising a plurality of silicon germanium (SiGe) channel layers and the N-channel metal-oxide-semiconductor (NMOS) transistor comprising a plurality of silicon (Si) channel layers.

16. The CFET device of claim 15, further comprising a gate region on the top surface of the N-channel metal-oxide-semiconductor (NMOS) transistor, the gate region including a gate material and a gate hard mask layer on the gate material.

17. The CFET device of claim 15, wherein the N-channel metal-oxide-semiconductor (NMOS) transistor comprises alternating layers of the plurality of silicon (Si) channel layers and a corresponding plurality of oxide layers.

18. The CFET device of claim 17, wherein the plurality of oxide layers comprises silicon oxide (SiOx).

19. The CFET device of claim 15, wherein the P-channel metal-oxide-semiconductor (PMOS) transistor comprises alternating layers of the plurality of the silicon germanium (SiGe) channel layers and a corresponding plurality of inner spacer layers and recessed nanosheet release layers.

20. The CFET device of claim 15, wherein the middle dielectric isolation layer comprises a low-K dielectric material.
